(19) United States
(12) Patent Application Publication
(10) Pub. No.: US 2024/0320710 A1
(43) Pub. Date: Sep. 26, 2024

(54) SYSTEMS AND METHODS FOR CONTENT DISTRIBUTION USING MACHINE LEARNING

(71) Applicant: ADOBE INC., SAN JOSE, CA (US)

(72) Inventors: Rebecca Dorothy West, Auburn, CA (US); Lauren Dest, Austin, TX (US); Mihir Naware, Redwood City, CA (US); Elliot Axel Patrick Puzenat, Le Plessis Robinson (FR); Stephen Becigneul, Levallois-Perret (FR); Alexis Tessier, Eckwersheim, Bas-Rhin (FR); Suman Basetty, Fremont, CA (US); Kimberly K. Lenox, Orinda, CA (US); Anil Kamath, Los Altos HIlls, CA (US)

(21) Appl. No.: 18/477,693

(22) Filed: Sep. 29, 2023

Related U.S. Application Data
(60) Provisional application No. 63/491,499, filed on Mar. 21, 2023.

(51) Int. Cl. G06Q 30/0251; G06N 3/0455; G06N 3/084

(52) U.S. Cl. CPC G06Q 30/0254; G06N 3/0455; G06N 3/084

(57) ABSTRACT

A method, non-transitory computer readable medium, apparatus, and system for content distribution are described. An embodiment of the present disclosure includes receiving, by a machine learning model, a prompt. The machine learning model generates a campaign brief based on the prompt. The campaign brief includes an identification of a user segment, an identification of a communication channel, and a content element. The machine learning model is trained using training data including a plurality of campaign briefs. A user experience platform provides content corresponding to the content element to a user from the user segment via the communication channel based on the campaign brief.

### CROSS-REFERENCE TO RELATED APPLICATION

This application claims the benefit, under 35 U.S.C. § 119, of the filing date of U.S. Provisional Application No. 63/491,499, filed on Mar. 21, 2023, in the United States Patent and Trademark Office. The disclosure of U.S. Provisional Application No. 63/491,499 is incorporated by reference herein in its entirety.

### BACKGROUND

The following relates generally to content distribution, and more specifically to content distribution using machine learning. In some cases, content is distributed based on meaningful information learned from data processing. Data processing refers to a collection and manipulation of data to produce the meaningful information. Machine learning is an information processing field in which algorithms or models such as artificial neural networks are trained to make predictive outputs in response to input data without being specifically programmed to do so.

Content is often provided according to a content distribution campaign, in which particular content is targeted for particular groups of users. In some cases, a content distribution campaign is planned according to a campaign brief, where the campaign brief is informed by information included in or derived from a relevant set of data. However, a process of creating the campaign brief based on the relevant set of data is both time-intensive and labor-intensive. There is therefore a need in the art for a content distribution system that generates a campaign brief in an efficient manner.

### SUMMARY

Embodiments of the present disclosure provide a content distribution system that uses a machine learning model to generate a content distribution campaign brief based on a prompt. In some cases, the content distribution system provides content described by the campaign brief to a user identified by the campaign brief according to a content distribution channel identified by the campaign brief.

Accordingly, by generating the campaign brief using the machine learning model, the content distribution system avoids a time-consuming and labor-intensive process used by conventional content distribution systems of manually creating a campaign brief. Furthermore, by providing content to the identified user according to the generated campaign brief, the content distribution system is able to provide targeted content to a target user in a more efficient manner than conventional content distribution systems.

A method, apparatus, non-transitory computer readable medium, and system for content distribution are described. One or more aspects of the method, apparatus, non-transitory computer readable medium, and system include receiving a prompt; generating, using a machine learning model, a campaign brief based on the prompt, wherein the campaign brief includes an identification of a user segment, an identification of a communication channel, and a content element, and wherein the machine learning model is trained using training data including a plurality of campaign briefs; and providing content corresponding to the content element to a user from the user segment via the communication channel based on the campaign brief.

A method, apparatus, non-transitory computer readable medium, and system for content distribution are described. One or more aspects of the method, apparatus, non-transitory computer readable medium, and system include obtaining training data that includes a training prompt and a ground-truth campaign brief and training a machine learning model to generate a campaign brief including an identification of a user segment, an identification of a communication channel, and a content element using the training data.

An apparatus and system for content distribution are described. One or more aspects of the apparatus and system include at least one processor; at least one memory storing instructions executable by the at least one processor; a machine learning model including language model parameters stored in the at least one memory and trained to generate a campaign brief based on a prompt, wherein the campaign brief includes an identification of a user segment, an identification of a communication channel, and a content element; and a user experience platform configured to provide content corresponding to the content element to a user from the user segment via the communication channel based on the campaign brief.

### BRIEF DESCRIPTION OF THE DRAWINGS

FIG. 1 shows an example of a content distribution system according to aspects of the present disclosure.

FIG. 2 shows an example of a content distribution apparatus according to aspects of the present disclosure.

FIG. 3 shows an example of a transformer according to aspects of the present disclosure.

FIG. 4 shows an example of data flow in a content distribution system according to aspects of the present disclosure.

FIG. 5 shows an example of a method for content distribution according to aspects of the present disclosure.

FIG. 6 shows an example of a method for providing content based on a campaign brief according to aspects of the present disclosure.

FIG. 7 shows an example of a user interface for campaign generation according to aspects of the present disclosure.

FIG. 8 shows an example of a user interface for campaign generation based on a user segment according to aspects of the present disclosure.

FIG. 9 shows an example of a user interface for a content distribution campaign according to aspects of the present disclosure.

FIG. 10 shows an example of a user interface for a modified content distribution campaign according to aspects of the present disclosure.

FIG. 11 shows an example of a user interface for evaluating a performance of a content distribution campaign according to aspects of the present disclosure.

FIG. 12 shows an example of a user interface for modification of a campaign according to aspects of the present disclosure.

FIG. 13 shows an example of a method for training a machine learning model according to aspects of the present disclosure.

### DETAILED DESCRIPTION

In some cases, content is distributed based on meaningful information learned from data processing. Data processing refers to a collection and manipulation of data to produce the meaningful information. Machine learning is an information processing field in which algorithms or models such as artificial neural networks are trained to make predictive outputs in response to input data without being specifically programmed to do so.

Content is often provided according to a content distribution campaign, in which particular content is targeted at particular groups of users. In some cases, a content distribution campaign is planned according to a campaign brief, where the campaign brief is informed by information included in or derived from a relevant set of data. However, a process of creating the campaign brief based on the relevant set of data is both time-intensive and labor-intensive.

For example, in some cases, content distribution and user experience strategies are informed by a wide variety of factors, including ever-changing market trends, user preferences, and signals from social, economic, and political landscapes. An ability to quickly and intelligently understand, plan for, and react to such factors greatly assists a content provider in achieving its goals.

At the same time, users are increasingly embracing digital channels to engage with content providers and are demanding that content providers personalize their interactions. Therefore, both users and content providers benefit when an intent, stage, and context of users are understood and a digital experience is tailored for the users. In some cases, a confluence of personalization at scale along with a myriad of macro influences presents an opportunity for a content distribution system for digital user experience management that operates at a granularity of an individual user's journey and sequence of experiences, all while helping a content provider to achieve its goals.

However, producing an effective content distribution campaign by synthesizing external and internal data into actionable opportunities, creating superior campaign components (e.g., content, journeys, objectives, etc.), and optimizing a content distribution strategy over time is not easily achievable for a content provider team, and added challenges of a demand from content providers for new, fresh, and personalized user experiences and siloed teams balancing various overlapping efforts creates further complication for creating an effective campaign.

For example, in some cases, a superior campaign draws upon vast and disparate external and internal data that individual strategists and analysts are not able to effectively comprehend or synthesize within an allotted time. In some cases, a significant part of an analyst's time is spent on retrieving basic key performance indicator (KPI) questions with little bandwidth for deep analysis, while in some cases, strategists such as campaign owners and managers rely on an ad hoc analysis of internal and external sources from analysts to come to a point solution campaign.

Furthermore, in some cases, a process of conceiving, executing, and evaluating a campaign is laborious and time-consuming and is constrained both by a number of available team members and an ability to rapidly and effectively respond to quickly moving user preferences. For example, in some cases, a conventional process for creating a campaign brief includes one or more of determining a campaign objective, a channel for content distribution, a program for content distribution, a target audience, and content to be distributed. Additionally, in some cases, an end-to-end content distribution effort is scattered across different roles, making an ability to quickly and dynamically adjust campaign components based on ever-changing trends a challenge.

For example, in some cases, strategists rely on operations teams, creative teams, and other team members to execute a point solution campaign. During such a process, in some cases, a performance-based adjustment to the campaign is time-consuming, as the adjustment demands waiting for a full cycle to re-engage team members that are now occupied with different tasks. Additionally, in some cases, a content distribution effort is hampered by a lack of healthy knowledge-sharing practices across teams, resulting in silos, inefficiencies, and bottlenecks.

Still further, in some cases, content distribution workflows are heavy, manual, and dependent upon a constant supply of human ingenuity and accuracy. For example, in some cases, operations team members that are focused on building user journeys perform numerous iterations according to an intuition of what aspects of a prospective user journey might be effective. Additionally, in some cases, creative team members have a limited capacity to create variations of content for campaigns, particularly based on historical performance and content affinity variations for clients and consumers.

Additionally, in some cases, an ability to create a tailored experience and user journey for each unique user is constrained by an ability of content provider teams to generate and deliver appropriate content at an appropriate time.

According to some aspects, a content distribution system includes a machine learning model and a user experience platform. In some cases, the machine learning model is trained to generate a campaign brief based on a prompt. In some cases, the campaign brief includes an identification of a user segment, an identification of a communication channel, and a content element. In some cases, the machine learning model is trained using training data including a set of campaign briefs. In some cases, the user experience platform is configured to provide content corresponding to the content element to a user from the user segment via the communication channel based on the campaign brief.

Accordingly, by generating the campaign brief using the machine learning model, the content distribution system avoids a time-consuming and labor-intensive process used by conventional content distribution systems of manually creating a campaign brief. Furthermore, by providing content to the identified user according to the generated campaign brief, the content distribution system is able to provide targeted content to a target user in a more efficient manner than conventional content distribution systems.

A content distribution system according to an aspect of the present disclosure is used in a content distribution campaign context. In an example, a user experience platform of the content distribution system identifies a trend in solo traveling among users who travel, and identifies user segments (such as a dual income, no kids user segment, a retirees user segment, and a business travelers user segment) that include users who are likely to travel by themselves. The user experience platform displays an opportunity relating to the data trend suggesting that the content provider should use the content distribution system to generate a content distribution campaign targeting the solo-traveling user segments to drive user bookings of a loyalty club promoted by the content provider.

Based on the identified data trend, the user experience platform generates a prompt including contextual information (such as one or more of data corresponding to the data trend, data corresponding to information displayed on a user interface, a content provider profile for the content provider, content provider preferences such as the campaign objective of driving user bookings of a loyalty club, a content provider playbook, a historical content distribution campaign for the content provider, the targeted solo-traveling user segments, a key performance indicator, a user journey for the content provider, previous content provider feedback, and any other available content provider information or user information) and an instruction to generate a campaign brief based on the contextual information.

The user experience platform provides the prompt as input to the machine learning model, and the machine learning model generates the campaign brief based on the prompt. In some cases, the campaign brief includes text comprising an identification of a user segment, an identification of a communication channel, and a content element. In an example, the campaign brief includes a keyword for retrieving an image preferred by the content provider, an identification of a social media platform for providing the image through, an identification of a user segment (e.g., dual income, no kids) including users that the image should be provided to, and a time period in which the image should be provided. In an example, the campaign brief includes instructions or code (such as a macro) for the user experience platform to execute to perform a function, such as retrieving, generating, and/or displaying content.

The machine learning platform provides the campaign brief to the user experience platform. In response to a content provider selection of a campaign preview element of the user interface, the user experience platform displays a visual representation of the campaign brief (for example, including a campaign timeline, an identification of the campaign goal, the targeted user segment, and the content to be provided) to the content provider via the user interface.

The user experience platform provides the content to a user of the user segment via the content channel according to the campaign brief. In an example, the user experience platform sends the image for display in a dual income, no kids user's social media feed. In some cases, the user experience platform provides the content in response to a content provider approval of the content.

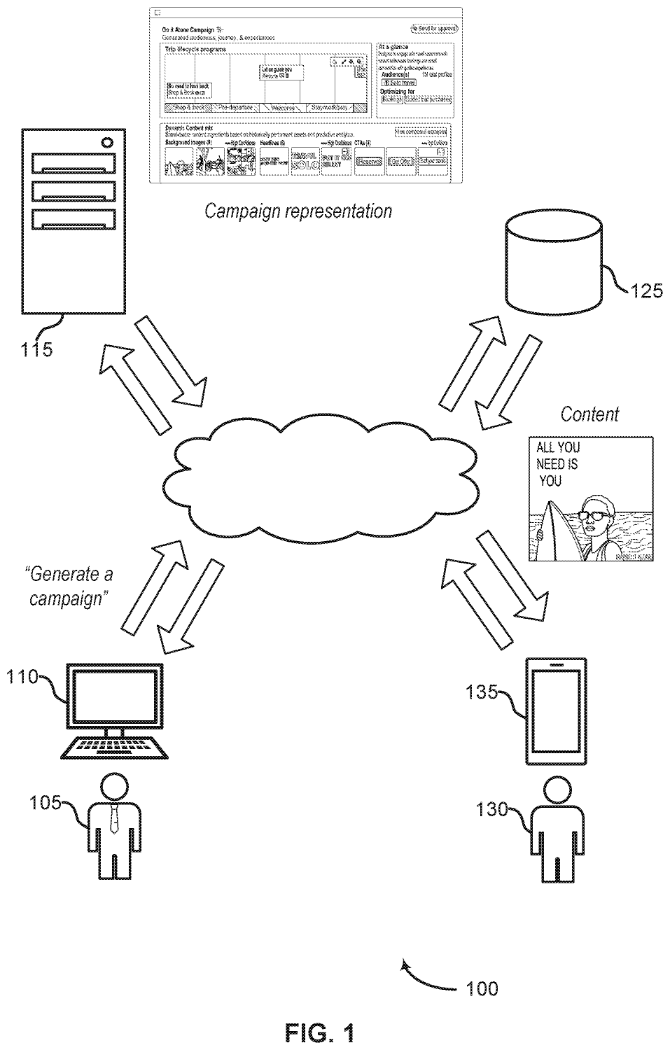

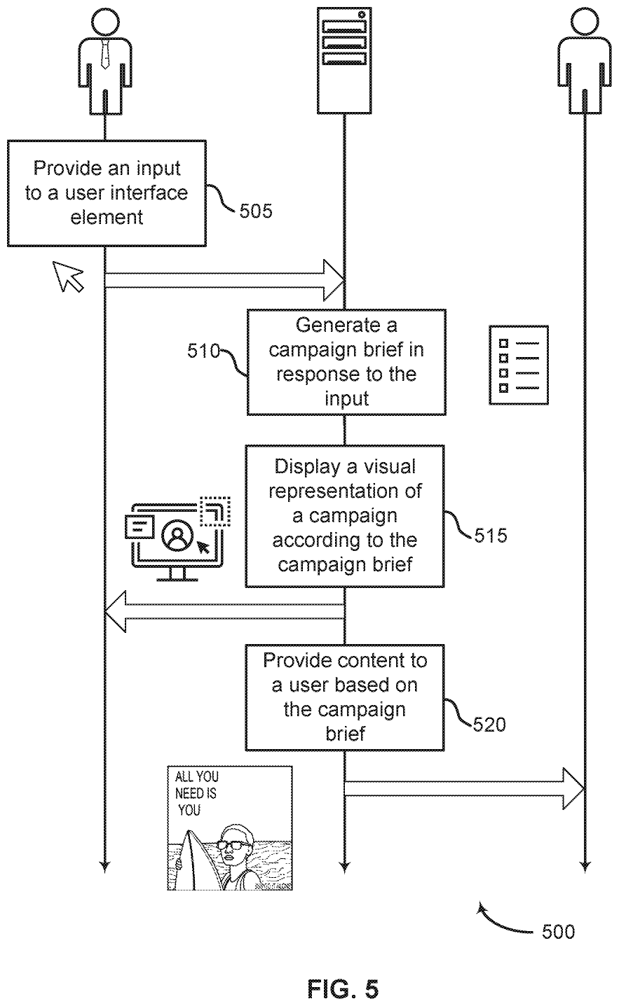

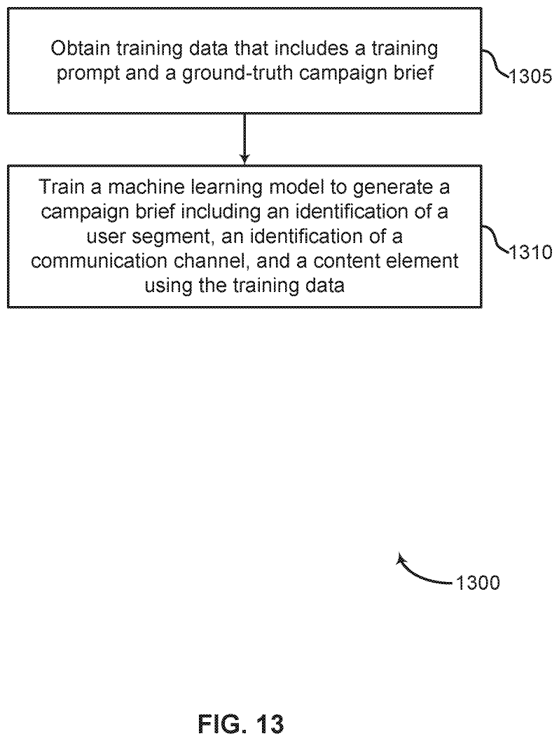

Further example applications of the present disclosure in the content distribution campaign context are provided with reference to FIGS. 1 and 5. Details regarding the architecture of the content distribution system are provided with reference to FIGS. 1-4. Details regarding a process for content distribution are provided with reference to FIGS. 5-12. Details regarding a process for training a machine learning model are provided with reference to FIG. 13.

As used herein, a “prompt” refers to an input to the machine learning model. In some cases, the prompt includes a natural language input. As used herein, “natural language” refers to any language that has emerged through natural use. In some cases, the prompt is generated by the user experience platform. In some cases, the prompt is generated in response to a content provider input to an element of a user interface. In some cases, the prompt includes contextual information, such as one or more of data corresponding to a data trend or anomaly, a text description of a suggested content distribution campaign provided by the content generation apparatus, data corresponding to information displayed on a user interface, a content provider profile for the content provider, content provider preferences (such as a campaign objective, a campaign goal, a preferred user segment, a preferred communication channel, preferred content, etc.), a content provider playbook, a historical content distribution campaign for the content provider, the targeted solo-traveling user segments, a key performance indicator, a user journey for the content provider, previous content provider feedback, and any other available content provider information or user information. In some cases, the prompt includes an instruction for the machine learning model to generate an output specified by the instruction. In some cases, the prompt comprises text (such as natural language text) provided by the content provider to the user interface. In some cases, the prompt includes one or more embeddings.

As used herein, in some cases, a “user experience platform” includes a set of creative, analytics, social, advertising, media optimization, targeting, Web experience management, journey orchestration and content management tools. In some cases, a user experience platform comprises one or more ANNs trained to generate content. In some cases, a user experience platform provides the user interface. In some cases, the user experience platform communicates with a database. In some cases, the user experience platform comprises the database.

As used herein, “content” refers to any form of media, including goods, services, physically tangible media, and the like, and digital content, including media such as text, audio, images, video, or a combination thereof. As used herein, a “content element” refers to content or a description of content. In some cases, a content element includes text-based content such as copy, subject headlines, hashtags, text for inclusion in an image, etc. In some cases, a content element includes one or more keywords to identify content based on data (such as metadata) associated with the content. In some cases, a content element includes a description for generating content using a text-based generation model (such as a text-to-image generation model). In some cases, a user experience platform retrieves and/or generates content based on a content element. In some cases, a content element includes instructions for generating content by combining content (for example, by including text described by the content element in an image described by the content element).

As used herein, in some cases, a “content provider” refers to a person or entity that interacts with the content distribution system and/or content distribution apparatus. As used herein, in some cases, a “content provider preference” refers to any information provided by the content provider to the content distribution system. In some cases, a content provider preference includes one or more of a preferred content, a preferred communication channel, a preferred campaign objective, a preferred user segment, a preferred time period for content distribution, and any other information that is used in developing a content distribution campaign for a content provider.

As used herein, a “content distribution campaign”, “communication campaign”, or “campaign” refers to a coordinated distribution of content through one or more content channels in order to achieve one or more goals, such as a number of product purchases, a number of content views, a number of sign-ups, etc.

In some cases, a content distribution campaign is planned according to a campaign brief. As used herein, a “campaign brief” refers to text including a description of one or more components or elements of a content distribution campaign, such as an identification of one or more of content to be distributed, an identification of a user segment for receiving the distributed content, a channel for distributing the content through, and a period (either stage-based or calendar-based) for distributing the content. As used herein, “stage-based” refers to periods determined according to an order of occurrence. As used herein, “calendar-based” refers to periods determined according to calendar dates.

In some cases, a campaign brief defines aspects of a campaign, including one or more of a target audience, a key performance indicator (KPI), an objective for the campaign, a timeframe for providing content according to the campaign, personnel assignments, campaign budget information, and content associated with the campaign. In some cases, the campaign brief is a roadmap for a content provider to execute on and a source of truth for the campaign.

According to some aspects, a campaign brief includes instructions or code executable by the user experience platform (e.g., a macro) to perform a function, such as retrieving or generating content.

As used herein, a “user segment” refers to a group of users corresponding to a group of user profiles and identified by a group of user identifiers. As used herein, a “user profile” refers to data corresponding to a user. Examples of data corresponding to a user include a name, contact information, demographic data, user device information, a purchase history, a correspondence history, and any other data relating to the user. As used herein, a “user identifier” refers to a unique identifier (such as a name, an email address, an identification number, etc.) for a user. In some cases, a user profile includes a user identifier. In some cases, the user segment includes one or more users corresponding to user profiles that include a common attribute or quality.

As used herein, a “communication channel” or a “content channel” refers to a physical channel (such as a mailing service, a physical location such as a store, a hotel, an amusement park, etc., and the like) through which content is provided. As used herein, a “digital content channel” refers to a channel through which digital content is provided, such as a website, a software application, an Internet-based application, an email service, a messaging service (such as SMS, instant messaging, etc.), a television service, a telephone service, etc. As used herein, “customized content” refers to content that is customized according to data associated with a content provider or a user.

According to some aspects, the content distribution system streamlines and enhances an end-to-end content distribution campaign, from planning to ideation and execution, through monitoring and optimization via machine learning. In an example, a machine learning model generates a campaign brief, and a user experience platform distributes content according to the generated campaign brief.

Accordingly, in some cases, because the campaign brief is generated by a machine learning model trained using training data including a set of campaign briefs, the content distribution system provides a campaign brief in a less time-consuming and labor-intensive manner than conventional content distribution systems. Furthermore, in some cases, because the campaign brief is efficiently generated, targeted content is identified and provided to a target user segment in a more efficient and less time-consuming manner than conventional content distribution systems provide.

According to some aspects, the content distribution system streamlines and enhances an end-to-end content distribution campaign, from planning to ideation and execution, through monitoring and optimization via machine learning. In an example, in some cases, the machine learning model generates an insight and/or an opportunity based on external data, user historical data, and capabilities of the user experience platform. In some cases, the synthesis and summarizing skills of the machine learning model are employed to proactively alert a content provider of an insight and/or an opportunity that align with objectives of the content provider.

According to some aspects, the content distribution system assists with an ideation, definition, expansion, and refinement of an audience for the content distribution campaign. For example, in some cases, the machine learning model qualifies and quantifies the audience using summary statistics and described traits of the audience along with projected performance of the audience towards the content distribution objective of the content provider.

According to some aspects, the content distribution system employs at least one of the user experience platform and the machine learning model to generate a complete content distribution campaign, including a program, messaging, content, and journey, or a combination thereof. For example, in some cases, the content distribution system optimizes the content distribution campaign for a target audience to meet the content distribution objective of the content provider.

According to some aspects, the content distribution system infuses capabilities of the machine learning model with capabilities of the user experience cloud to provide a multi-modal conversational interface capable of brainstorming, ideation, and reasoning, that retains and adapts to context. In some cases, the conversational interface is implemented as a copilot for user experience management.

According to some aspects, the content distribution system is directed by additional inputs and/or dimensions to dynamically and continuously regenerate generated outputs. According to some aspects, journeys, journey simulation, and performance predictions are based on historical journey data of a content provider combined with external journey data leveraged by the machine learning model.

Furthermore, unlike conventional content distribution systems which use employ generative machine learning, according to some aspects, the content distribution system goes beyond image and text generation to deliver insights and opportunities to a content provider to create a content distribution package in addition to text and image content, such as harmonious multimodal experiences and performant content that leverages content insights from user's data and content. According to some aspects, the content distribution system includes a comprehensive user experience management suite for planning, execution, and analysis to execute personalization-at-scale strategies. According to some aspects, the content distribution system integrates workflows for experience creation and delivery so that there is no need for a content provider to employ another system.

Accordingly, in some cases, the content distribution system provides a content provider with efficiency, efficacy, scale, agility, velocity, ideation, collaboration, and/or execution, thereby allowing the content provider to do more with less.

### Content Distribution System

A system and an apparatus for content distribution are described with reference to FIGS. 1-4. One or more aspects of the system and the apparatus include at least one processor; at least one memory storing instructions executable by the at least one processor; a machine learning model including language model parameters stored in the at least one memory and trained to generate a campaign brief based on a prompt, where the campaign brief includes an identification of a user segment, an identification of a communication channel, and a content element; and a user experience platform configured to provide content corresponding to the content element to a user from the user segment via the communication channel based on the campaign brief.

In some aspects, the campaign brief identifies a plurality of audiences including the user segment. In some aspects, the campaign brief identifies one or more campaign objectives. In some aspects, the campaign brief identifies a plurality of periods and a program for each of the plurality of periods, wherein the communication channel is associated with the program for at least one of the plurality of periods. In some aspects, the campaign brief includes a plurality of content elements.

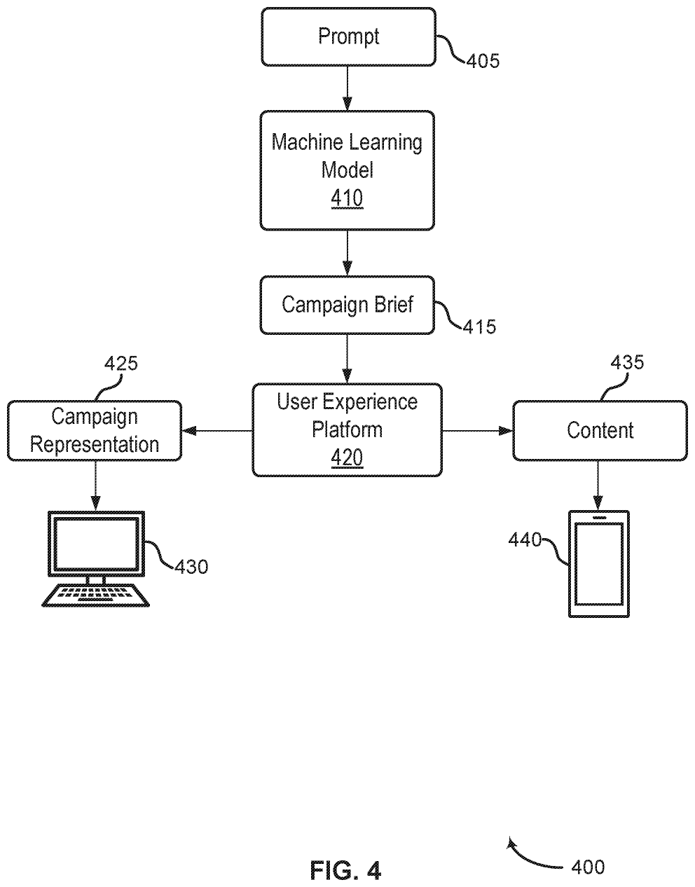

FIG. 1 shows an example of a content distribution system 100 according to aspects of the present disclosure. The example shown includes content provider 105, content provider device 110, content distribution apparatus 115, cloud 120, database 125, user 130, and user device 135. Content distribution system 100 is an example of, or includes aspects of, the corresponding element described with reference to FIG. 4.

Referring to FIG. 1, according to an aspect of the present disclosure, content distribution system 100 is used in a content distribution campaign context. In an example, content provider 105 provides a text input to content distribution apparatus 115 instructing content distribution apparatus 115 to generate a content distribution campaign for the content provider. Content provider 105 provides the text input via a user interface provided on content provider device 110 by content distribution apparatus 115. In response to the instruction, a user experience platform of content distribution apparatus 115 generates a prompt including textual information and an instruction for a machine learning model of content distribution apparatus 115 to generate a campaign brief.

In response to the prompt, the machine learning model generates the campaign brief describing a content distribution campaign for the content provider, including an identification of content, a user segment, and a communication channel. The user experience platform generates a representation of the content distribution campaign based on the campaign brief and displays the representation to content provider 105 via the user interface. Content provider 105 approves the campaign by providing a content provider approval input to the user interface. In response to the approval, content distribution apparatus 115 distributes the content generated according to the campaign brief to user 130 of the user segment via user device 135 and the communication channel.

Content provider device 110 is an example of, or includes aspects of, the corresponding element described with reference to FIG. 4. According to some aspects, content provider device 110 is a personal computer, laptop computer, mainframe computer, palmtop computer, personal assistant, mobile device, or any other suitable processing apparatus. In some examples, content provider device 110 includes software that displays the user interface (e.g., the graphical user interface) provided by content distribution apparatus 115. In some aspects, the user interface allows information (such as text, an image, etc.) to be communicated between content provider 105 and content distribution apparatus 115.

According to some aspects, a content provider device user interface enables content provider 105 to interact with content provider device 110. In some embodiments, the content provider device user interface includes an audio device, such as an external speaker system, an external display device such as a display screen, or an input device (e.g., a remote-control device interfaced with the user interface directly or through an I/O controller module). In some cases, the content provider device user interface is a graphical user interface.

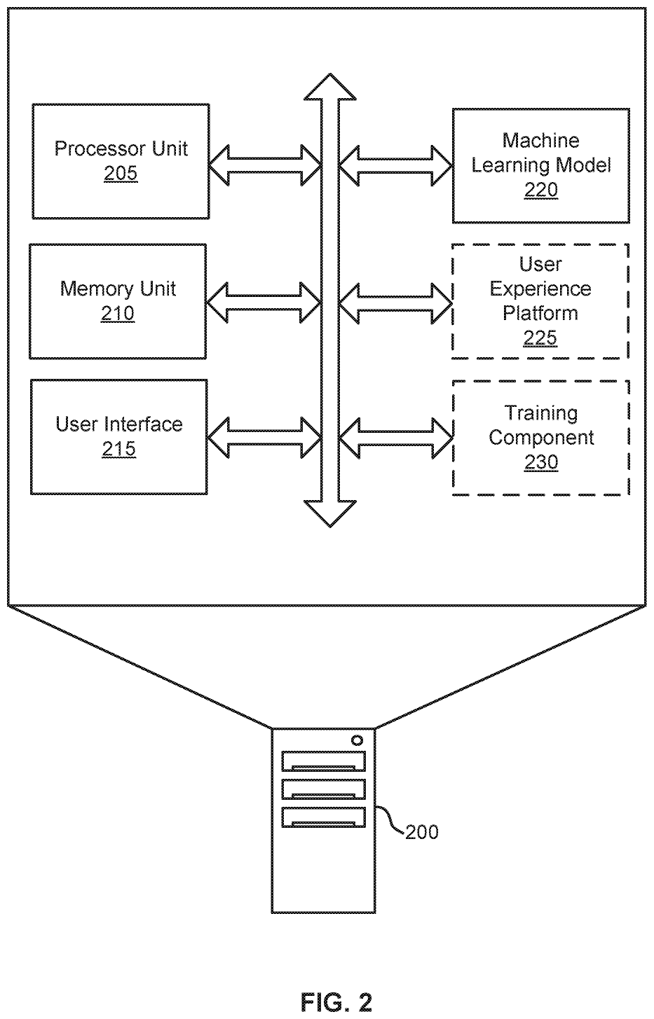

Content distribution apparatus 115 is an example of, or includes aspects of, the corresponding element described with reference to FIG. 2. According to some aspects, content distribution apparatus 115 includes a computer-implemented network. In some embodiments, the computer-implemented network includes a machine learning model (such as the machine learning model described with reference to FIGS. 2 and 4). In some embodiments, content distribution apparatus 115 also includes one or more processors, a memory subsystem, a communication interface, an I/O interface, one or more user interface components, and a bus. Additionally, in some embodiments, content distribution apparatus 115 communicates with content provider device 110 and database 125 via cloud 120.

In some cases, content distribution apparatus 115 is implemented on a server. A server provides one or more functions to content providers linked by way of one or more of various networks, such as cloud 120. In some cases, the server includes a single microprocessor board, which includes a microprocessor responsible for controlling all aspects of the server. In some cases, the server uses microprocessor and protocols to exchange data with other devices or content providers on one or more of the networks via one or more of hypertext transfer protocol (HTTP), simple mail transfer protocol (SMTP), file transfer protocol (FTP), and simple network management protocol (SNMP). In some cases, the server is configured to send and receive hypertext markup language (HTML) formatted files (e.g., for displaying web pages). In various embodiments, the server comprises a general-purpose computing device, a personal computer, a laptop computer, a mainframe computer, a supercomputer, or any other suitable processing apparatus.

Further detail regarding the architecture of content distribution apparatus 115 is provided with reference to FIGS. 2-4. Further detail regarding a process for content distribution is provided with reference to FIGS. 5-12. Further detail regarding a process for training a machine learning model is provided with reference to FIG. 13.

Cloud 120 is a computer network configured to provide on-demand availability of computer system resources, such as data storage and computing power. In some examples, cloud 120 provides resources without active management by a content provider. The term “cloud” is sometimes used to describe data centers available to many content providers over the Internet.

Some large cloud networks have functions distributed over multiple locations from central servers. A server is designated an edge server if it has a direct or close connection to a content provider. In some cases, cloud 120 is limited to a single organization. In other examples, cloud 120 is available to many organizations.

In one example, cloud 120 includes a multi-layer communications network comprising multiple edge routers and core routers. In another example, cloud 120 is based on a local collection of switches in a single physical location. According to some aspects, cloud 120 provides communications between content provider device 110, content distribution apparatus 115, database 125, and user device 135.

Database 125 is an example of, or includes aspects of, the corresponding element described with reference to FIG. 4. Database 125 is an organized collection of data. In an example, database 125 stores data in a specified format known as a schema. According to some aspects, database 125 is structured as a single database, a distributed database, multiple distributed databases, or an emergency backup database. In some cases, a database controller manages data storage and processing in database 125 via manual interaction or automatically without manual interaction. According to some aspects, database 125 is external to content distribution apparatus 115 and communicates with content distribution apparatus 115 via cloud 120. According to some aspects, database 125 is included in content distribution apparatus 115.

User device 135 is an example of, or includes aspects of, the corresponding element described with reference to FIG. 4. According to some aspects, user device 135 is a personal computer, laptop computer, mainframe computer, palmtop computer, personal assistant, mobile device, or any other suitable processing apparatus. In some aspects, a user interface provided on user device 135 (for example, by content distribution apparatus 115 or an external system in communication with content distribution apparatus 115) allows content to be communicated by content distribution apparatus 115 to user 130.

According to some aspects, a user device user interface enables user 130 to interact with user device 135. In some embodiments, the user device user interface includes an audio device, such as an external speaker system, an external display device such as a display screen, or an input device (e.g., a remote-control device interfaced with the user interface directly or through an I/O controller module). In some cases, the user device user interface is a graphical user interface.

FIG. 2 shows an example of a content distribution apparatus 200 according to aspects of the present disclosure. Content distribution apparatus 200 is an example of, or includes aspects of, the corresponding element described with reference to FIG. 1. In one aspect, content distribution apparatus 200 includes processor unit 205, memory unit 210, user interface 215, machine learning model 220, user experience platform 225, and training component 230.

Processor unit 205 includes one or more processors. A processor is an intelligent hardware device, such as a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or any combination thereof.

In some cases, processor unit 205 is configured to operate a memory array using a memory controller. In other cases, a memory controller is integrated into processor unit 205. In some cases, processor unit 205 is configured to execute computer-readable instructions stored in memory unit 210 to perform various functions. In some aspects, processor unit 205 includes special purpose components for modem processing, baseband processing, digital signal processing, or transmission processing.

Memory unit 210 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause at least one processor of processor unit 205 to perform various functions described herein.

In some cases, memory unit 210 includes a basic input/output system (BIOS) that controls basic hardware or software operations, such as an interaction with peripheral components or devices. In some cases, memory unit 210 includes a memory controller that operates memory cells of memory unit 210. For example, in some cases, the memory controller includes a row decoder, column decoder, or both. In some cases, memory cells within memory unit 210 store information in the form of a logical state.

User interface 215 is an example of, or includes aspects of, the corresponding element described with reference to FIGS. 4, and 7-12. According to some aspects, user interface 215 provides for communication between a content provider device (such as the content provider device described with reference to FIG. 1) and content distribution apparatus 200. For example, in some cases, user interface 215 is a graphical user interface (GUI) provided on the content provider device by content distribution apparatus 200. According to some aspects, user interface 215 is configured to receive a content provider input. According to some aspects, user interface 215 is configured to display a representation of a content distribution campaign. According to some aspects, user interface 215 is configured to receive a prompt.

Machine learning model 220 is an example of, or includes aspects of, the corresponding element described with reference to FIG. 4. According to some aspects, machine learning model 220 is implemented as software stored in memory unit 210 and executable by processor unit 205, as firmware, as one or more hardware circuits, or as a combination thereof. In some cases, machine learning model 220 is included in user experience platform 225. According to some aspects, machine learning model 220 comprises one or more artificial neural networks (ANNs) designed and/or trained to generate text (such as a campaign brief) based on a prompt.

An ANN is a hardware component or a software component that includes a number of connected nodes (i.e., artificial neurons) that loosely correspond to the neurons in a human brain. Each connection, or edge, transmits a signal from one node to another (like the physical synapses in a brain). When a node receives a signal, it processes the signal and then transmits the processed signal to other connected nodes.

In some cases, the signals between nodes comprise real numbers, and the output of each node is computed by a function of the sum of its inputs. In some examples, nodes determine their output using other mathematical algorithms, such as selecting the max from the inputs as the output, or any other suitable algorithm for activating the node. Each node and edge are associated with one or more node weights that determine how the signal is processed and transmitted.

In ANNs, a hidden (or intermediate) layer includes hidden nodes and is located between an input layer and an output layer. Hidden layers perform nonlinear transformations of inputs entered into the network. Each hidden layer is trained to produce a defined output that contributes to a joint output of the output layer of the ANN. Hidden representations are machine-readable data representations of an input that are learned from hidden layers of the ANN and are produced by the output layer. As the understanding of the ANN of the input improves as the ANN is trained, the hidden representation is progressively differentiated from earlier iterations.

During a training process of an ANN, the node weights are adjusted to improve the accuracy of the result (i.e., by minimizing a loss which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

According to some aspects, machine learning model 220 includes machine learning parameters stored in memory unit 210. Machine learning parameters are variables that provide a behavior and characteristics of a machine learning model. In some cases, machine learning parameters are learned or estimated from training data and are used to make predictions or perform tasks based on learned patterns and relationships in the data.

In some cases, machine learning parameters are adjusted during a training process to minimize a loss function or to maximize a performance metric. The goal of the training process is to find optimal values for the parameters that allow the machine learning model to make accurate predictions or perform well on a given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

In some cases, parameters of an ANN include weights and biases associated with each neuron in the ANN that control a strength of connections between neurons and influence the ability of the ANN to capture complex patterns in data.

According to some aspects, machine learning model 220 comprises a large language model. A large language model is a machine learning model that is designed and/or trained to learn statistical patterns and structures of human language. Large language models are capable of a wide range of language-related tasks such as text completion, question answering, translation, summarization, and creative writing, in response to a prompt. In some cases, the term “large” refers to a size and complexity of the large language model, usually measured in terms of a number of parameters of the large language model, where more parameters allow a large language model to understand more intricate language patterns and generate more nuanced and coherent text.

In some cases, the large language model comprises a sequence-to-sequence (seq2seq) model. A seq2seq model comprises one or more ANNs configured to transform a given sequence of elements, such as a sequence of words in a sentence, into another sequence using sequence transformation.

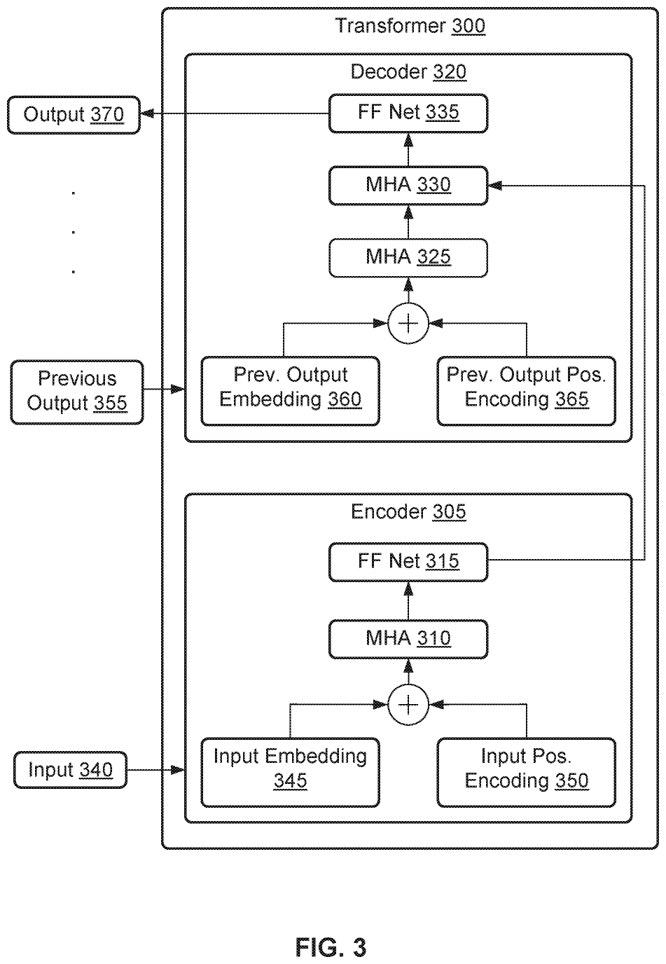

In some cases, machine learning model 220 comprises one or more transformers (such as the transformer described with reference to FIG. 3). In some cases, a transformer comprises one or more ANNs comprising attention mechanisms that enable the transformer to weigh an importance of different words or tokens within a sequence. In some cases, a transformer processes entire sequences simultaneously in parallel, making the transformer highly efficient and allowing the transformer to capture long-range dependencies more effectively.

In some cases, a transformer comprises an encoder-decoder structure. In some cases, the encoder of the transformer processes an input sequence and encodes the input sequence into a set of high-dimensional representations. In some cases, the decoder of the transformer generates an output sequence based on the encoded representations and previously generated tokens. In some cases, the encoder and the decoder are composed of multiple layers of self-attention mechanisms and feed-forward ANNs.

In some cases, the self-attention mechanism allows the transformer to focus on different parts of an input sequence while computing representations for the input sequence. In some cases, the self-attention mechanism captures relationships between words of a sequence by assigning attention weights to each word based on a relevance to other words in the sequence, thereby enabling the transformer to model dependencies regardless of a distance between words.

An attention mechanism is a key component in some ANN architectures, particularly ANNs employed in natural language processing (NLP) and sequence-to-sequence tasks, that allows an ANN to focus on different parts of an input sequence when making predictions or generating output.

NLP refers to techniques for using computers to interpret or generate natural language. In some cases, NLP tasks involve assigning annotation data such as grammatical information to words or phrases within a natural language expression. Different classes of machine-learning algorithms have been applied to NLP tasks. Some algorithms, such as decision trees, utilize hard if-then rules. Other systems use neural networks or statistical models which make soft, probabilistic decisions based on attaching real-valued weights to input features. In some cases, these models express the relative probability of multiple answers.

Some sequence models (such as recurrent neural networks) process an input sequence sequentially, maintaining an internal hidden state that captures information from previous steps. However, in some cases, this sequential processing leads to difficulties in capturing long-range dependencies or attending to specific parts of the input sequence.

The attention mechanism addresses these difficulties by enabling an ANN to selectively focus on different parts of an input sequence, assigning varying degrees of importance or attention to each part. The attention mechanism achieves the selective focus by considering a relevance of each input element with respect to a current state of the ANN.

In some cases, an ANN employing an attention mechanism receives an input sequence and maintains its current state, which represents an understanding or context. For each element in the input sequence, the attention mechanism computes an attention score that indicates the importance or relevance of that element given the current state. The attention scores are transformed into attention weights through a normalization process, such as applying a softmax function. The attention weights represent the contribution of each input element to the overall attention. The attention weights are used to compute a weighted sum of the input elements, resulting in a context vector. The context vector represents the attended information or the part of the input sequence that the ANN considers most relevant for the current step. The context vector is combined with the current state of the ANN, providing additional information and influencing subsequent predictions or decisions of the ANN.

In some cases, by incorporating an attention mechanism, an ANN dynamically allocates attention to different parts of the input sequence, allowing the ANN to focus on relevant information and capture dependencies across longer distances.

In some cases, calculating attention involves three basic steps. First, a similarity between a query vector Q and a key vector K obtained from the input is computed to generate attention weights. In some cases, similarity functions used for this process include dot product, splice, detector, and the like. Next, a softmax function is used to normalize the attention weights. Finally, the attention weights are weighed together with their corresponding values V. In the context of an attention network, the key K and value V are typically vectors or matrices that are used to represent the input data. The key K is used to determine which parts of the input the attention mechanism should focus on, while the value V is used to represent the actual data being processed.

According to some aspects, machine learning model 220 receives a prompt. According to some aspects, machine learning model 220 generates a campaign brief including an identification of a user segment, an identification of a communication channel, and a content element. In some aspects, the campaign brief identifies a set of audiences including the user segment. In some aspects, the campaign brief identifies one or more campaign objectives. In some aspects, the campaign brief identifies a set of periods and a program for each of the set of periods, where the communication channel is associated with the program for at least one of the set of periods. In some aspects, the set of content elements includes at least one text element and at least one visual element. In some examples, machine learning model 220 receives content provider feedback for the campaign brief and modifies the campaign brief based on the content provider feedback.

In some aspects, the campaign brief identifies a set of audiences including the user segment. In some aspects, the campaign brief identifies one or more campaign objectives. In some aspects, the campaign brief identifies a set of periods and a program for each of the set of periods, where the communication channel is associated with the program for at least one of the set of periods. In some aspects, the campaign brief includes a set of content elements. In some aspects, the set of content elements includes at least one text element and at least one visual element.

According to some aspects, machine learning model 220 is trained to generate a campaign brief including an identification of a user segment, an identification of a communication channel, and a content element. In some aspects, the campaign brief identifies a set of audiences including the user segment. In some aspects, the campaign brief identifies one or more campaign objectives. In some aspects, the campaign brief identifies a set of periods and a program for each of the set of periods, where the communication channel is associated with the program for at least one of the set of periods. In some aspects, the campaign brief includes a set of content elements.

User experience platform 225 is an example of, or includes aspects of, the corresponding element described with reference to FIG. 4. According to some aspects, user experience platform 225 is implemented as software stored in memory unit 210 and executable by processor unit 205, as firmware, as one or more hardware circuits, or as a combination thereof.

According to some aspects, user experience platform 225 is omitted from content distribution apparatus 200 and is implemented in at least one apparatus separate from content distribution apparatus 200 (for example, at least one apparatus comprised in a cloud, such as the cloud described with reference to FIG. 1). According to some aspects, the separate apparatus comprising user experience platform 225 communicates with content distribution apparatus 200 (for example, via the cloud) to perform the functions of user experience platform 225 described herein.

For example, in some cases, content distribution apparatus 200 is implemented as an edge server in a content distribution system (such as the content generation system described with reference to FIGS. 1 and 4), user experience platform 225 is included in a central server of the content distribution system, and content distribution apparatus 200 communicates with the central server to implement the functions of user experience platform 225 described herein.

According to some aspects, user experience platform 225 includes a set of creative, analytics, social, advertising, media optimization, targeting, Web experience management, journey orchestration and content management tools. In some cases, user experience platform 225 includes one or more of a graphic design component providing image generation and/or editing capabilities, a video editing component, a web development component, and a photography component. In some cases, user experience platform 225 comprises one or more of an enterprise content management component; a digital asset management component; an enterprise content distribution component that manages direct content distribution campaigns, leads, resources, user data, and analytics, and allows content providers to design and orchestrate targeted and personalized campaigns via channels such as direct mail, e-mail, SMS, and MMS; a data management component for data modeling and predictive analytics; and a web analytics system that provides web metrics, dimensions, and allows content provider to define tags implemented in webpage for web tracking to provide customized dimensions, metrics, segmentations, content provider reports, and dashboards.

In some cases, user experience platform 225 has comprehensive end-to-end capabilities with content distribution-specific technology across conceptualization, execution, and insights to merge with machine learning model 220 and generative machine learning experiences. In some cases, user experience platform 225 builds a cohesive user view, supporting but not limited to analytics, digital advertising, email, user data management, social media, call centers, and commerce. In some cases, user experience platform 225 consolidates, identifies, and builds full profiles from datasets that provide differentiating data for generating content that benefits from personalization.

According to some aspects, user experience platform 225 comprises one or more ANNs, and one or more components of user experience platform 225 are implemented via the one or more ANNs. In some cases, user experience platform 225 comprises one or more generative machine learning models configured to generate content.

According to some aspects, user experience platform 225 is configured to provide one or more user interface elements according to information included in a campaign brief. According to some aspects, user experience platform 225 is configured to display information in a corresponding user interface element according to information included in a campaign brief.

According to some aspects, user experience platform 225 generates the prompt. According to some aspects, user experience platform 225 provides content corresponding to the content element to a user from the user segment via the communication channel based on the campaign brief. In some examples, user experience platform 225 selectively includes content corresponding to the set of content elements in a set of communications corresponding to a set of user segments, respectively. In some examples, user experience platform 225 evaluates the campaign brief based on ethics, accessibility, intellectual property compliance, or any combination thereof.

According to some aspects, user experience platform 225 is configured to provide content corresponding to the content element to a user from the user segment via the communication channel based on the campaign brief.

According to some aspects, training component 230 is implemented as software stored in memory unit 210 and executable by processor unit 205, as firmware, as one or more hardware circuits, or as a combination thereof. According to some aspects, training component 230 is omitted from content distribution apparatus 200 and is implemented in at least one apparatus separate from content distribution apparatus 200 (for example, at least one apparatus comprised in a cloud, such as the cloud described with reference to FIG. 1). According to some aspects, the separate apparatus comprising training component 230 communicates with content distribution apparatus 200 (for example, via the cloud) to perform the functions of training component 230 described herein.

According to some aspects, training component 230 obtains training data that includes a training prompt and a ground-truth campaign brief. In some examples, training component 230 trains machine learning model 220 to generate a campaign brief including an identification of a user segment, an identification of a communication channel, and a content element using the training data. In some cases, training component 230 trains machine learning model 220 using training data including a set of campaign briefs.

FIG. 3 shows an example of a transformer 300 according to aspects of the present disclosure. The example shown includes transformer 300, encoder 305, decoder 320, input 340, input embedding 345, input positional encoding 350, previous output 355, previous output embedding 360, previous output positional encoding 365, and output 370.

In some cases, encoder 305 includes multi-head self-attention sublayer 310 and feed-forward network sublayer 315. In some cases, decoder 320 includes first multi-head self-attention sublayer 325, second multi-head self-attention sublayer 330, and feed-forward network sublayer 335.

According to some aspects, a machine learning model (such as the machine learning model described with reference to FIGS. 2 and 4) comprises transformer 300. In some cases, encoder 305 is configured to map input 340 (for example, a sequence of words or tokens, such as a prompt as described herein) to a sequence of continuous representations that are fed into decoder 320. In some cases, decoder 320 generates output 370 (e.g., a predicted sequence of words or tokens) based on the output of encoder 305 and previous output 355 (e.g., a previously predicted output sequence), which allows for the use of autoregression.

For example, in some cases, encoder 305 parses input 340 into tokens and vectorizes the parsed tokens to obtain input embedding 345, and adds input positional encoding 350 (e.g., positional encoding vectors for input 340 of a same dimension as input embedding 345) to input embedding 345. In some cases, input positional encoding 350 includes information about relative positions of words or tokens in input 340.

In some cases, encoder 305 comprises one or more encoding layers (e.g., six encoding layers) that generate contextualized token representations, where each representation corresponds to a token that combines information from other input tokens via self-attention mechanism. In some cases, each encoding layer of encoder 305 comprises a multi-head self-attention sublayer (e.g., multi-head self-attention sublayer 310). In some cases, the multi-head self-attention sublayer implements a multi-head self-attention mechanism that receives different linearly projected versions of queries, keys, and values to produce outputs in parallel. In some cases, each encoding layer of encoder 305 also includes a fully connected feed-forward network sublayer (e.g., feed-forward network sublayer 315) comprising two linear transformations surrounding a Rectified Linear Unit (ReLU) activation:

$$\\ \begin{matrix}FFN ( x ) = ReLU ( {W}_{1} x + {b}_{1} ) {W}_{2} + {b}_{2} & ( 1 )\end{matrix}$$

In some cases, each layer employs different weight parameters (W₁, W₂) and different bias parameters (b₁, b₂) to apply a same linear transformation each word or token in input 340.

In some cases, each sublayer of encoder 305 is followed by a normalization layer that normalizes a sum computed between a sublayer input x and an output sublayer(x) generated by the sublayer:

$$\\ \begin{matrix}layernorm ( x + sublayer ( x ) ) & ( 2 )\end{matrix}$$

In some cases, encoder 305 is bidirectional because encoder 305 attends to each word or token in input 340 regardless of a position of the word or token in input 340.

In some cases, decoder 320 comprises one or more decoding layers (e.g., six decoding layers). In some cases, each decoding layer comprises three sublayers including a first multi-head self-attention sublayer (e.g., first multi-head self-attention sublayer 325), a second multi-head self-attention sublayer (e.g., second multi-head self-attention sublayer 330), and a feed-forward network sublayer (e.g., feed-forward network sublayer 335). In some cases, each sublayer of decoder 320 is followed by a normalization layer that normalizes a sum computed between a sublayer input x and an output sublayer(x) generated by the sublayer.

In some cases, decoder 320 generates previous output embedding 360 of previous output 355 and adds previous output positional encoding 365 (e.g., position information for words or tokens in previous output 355) to previous output embedding 360. In some cases, each first multi-head self-attention sublayer receives the combination of previous output embedding 360 and previous output positional encoding 365 and applies a multi-head self-attention mechanism to the combination. In some cases, for each word in an input sequence, each first multi-head self-attention sublayer of decoder 320 attends only to words preceding the word in the sequence, and so transformer 300's prediction for a word at a particular position only depends on known outputs for a word that came before the word in the sequence. For example, in some cases, each first multi-head self-attention sublayer implements multiple single-attention functions in parallel by introducing a mask over values produced by the scaled multiplication of matrices Q and K by suppressing matrix values that would otherwise correspond to disallowed connections.

In some cases, each second multi-head self-attention sublayer implements a multi-head self-attention mechanism similar to the multi-head self-attention mechanism implemented in each multi-head self-attention sublayer of encoder 305 by receiving a query Q from a previous sublayer of decoder 320 and a key K and a value V from the output of encoder 305, allowing decoder 320 to attend to each word in the input 340.

In some cases, each feed-forward network sublayer implements a fully connected feed-forward network similar to feed-forward network sublayer 315. In some cases, the feed-forward network sublayers are followed by a linear transformation and a softmax to generate a prediction of output 370 (e.g., a prediction of a next word or token in a sequence of words or tokens). Accordingly, in some cases, transformer 300 generates a campaign brief as described herein based on a predicted sequence of words or tokens.

FIG. 4 shows an example of data flow in a content distribution system 400 according to aspects of the present disclosure. The example shown includes prompt 405, machine learning model 410, campaign brief 415, user experience platform 420, campaign representation 425, content provider device 430, content 435, and user device 440.

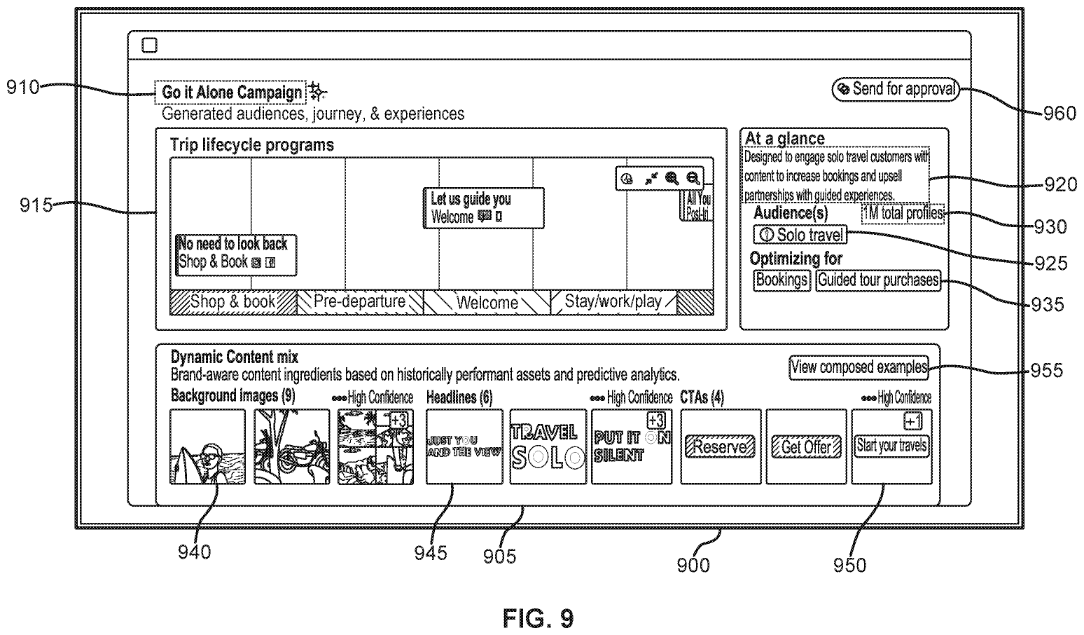

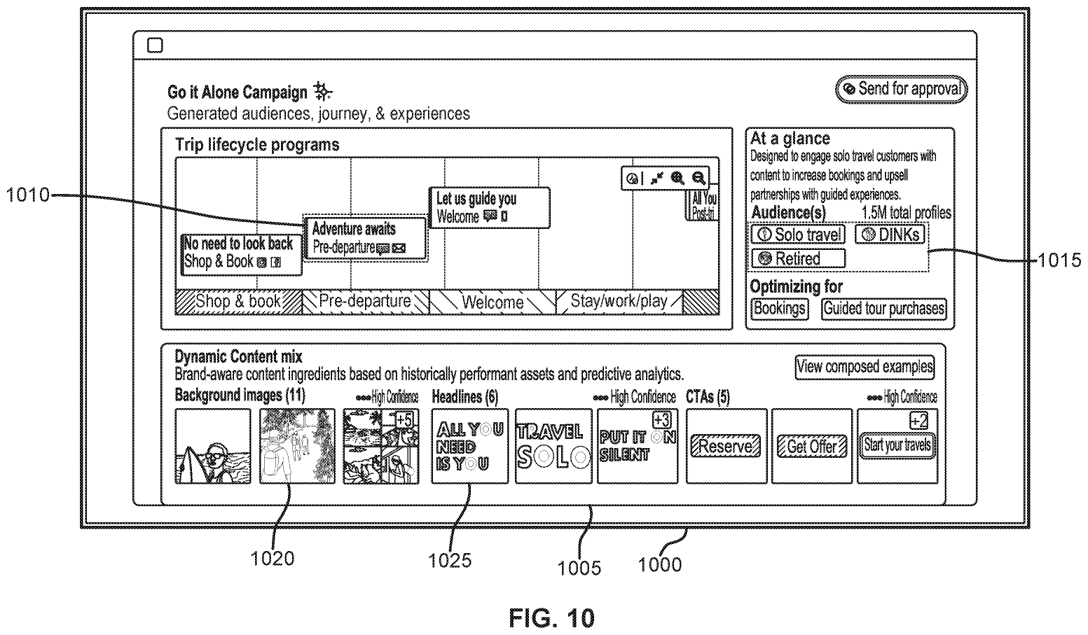

Content distribution system 400 is an example of, or includes aspects of, the corresponding element described with reference to FIG. 1. Machine learning model 410 is an example of, or includes aspects of, the corresponding element described with reference to FIG. 2. User experience platform 420 is an example of, or includes aspects of, the corresponding element described with reference to FIG. 2. Campaign representation 425 is an example of, or includes aspects of, the corresponding element described with reference to FIGS. 9 and 10. Content provider device 430 is an example of, or includes aspects of, the corresponding element described with reference to FIG. 1. User device 440 is an example of, or includes aspects of, the corresponding element described with reference to FIG. 1.

Referring to FIG. 4, according to some aspects, machine learning model 410 receives prompt 405. In some cases, user experience platform 420 provides prompt 405 to machine learning model 410. In some cases, a content provider (such as the content provider described with reference to FIG. 1) provides prompt 405 to machine learning model 410 (for example, via a user interface such as the user interface described with reference to FIGS. 2 and 7-12). According to some aspects, machine learning model 410 generates campaign brief 415 based on prompt 405. According to some aspects, machine learning model 410 provides campaign brief 415 to user experience platform 420.

According to some aspects, user experience platform 420 displays campaign representation 425 on content provider device 430 (for example, via the user interface). In some cases, user experience platform 420 retrieves and/or generates content 435 based on campaign brief 415. According to some aspects, user experience platform 420 provides content 435 via a communication channel identified by campaign brief 415 to user device 440 of a user identified by campaign brief 415.

### Content Distribution

A method for content distribution is described with reference to FIGS. 5-12. One or more aspects of the method include receiving a prompt; generating, using a machine learning model, a campaign brief based on the prompt, wherein the campaign brief includes an identification of a user segment, an identification of a communication channel, and a content element, wherein the machine learning model is trained using training data including a set of campaign briefs; and providing content corresponding to the content element to a user from the user segment via the communication channel based on the campaign brief.

In some aspects, the campaign brief identifies a plurality of audiences including the user segment. In some aspects, the campaign brief identifies one or more campaign objectives. In some aspects, the campaign brief identifies a plurality of periods and a program for each of the plurality of periods, wherein the communication channel is associated with the program for at least one of the plurality of periods. In some aspects, the campaign brief includes a plurality of content elements. In some aspects, the plurality of content elements includes at least one text element and at least one visual element.

Some examples of the method further include selectively including content corresponding to the plurality of content elements in a plurality of communications corresponding to a plurality of user segments, respectively. Some examples of the method further include evaluating the campaign brief based on ethics, accessibility, intellectual property compliance, or any combination thereof. Some examples of the method further include receiving content provider feedback for the campaign brief and modifying the campaign brief based on the content provider feedback using the machine learning model.

FIG. 5 shows an example of a method 500 for content distribution according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 5, according to an aspect of the present disclosure, a content distribution system (such as the content distribution system described with reference to FIGS. 1 and 4) is used in a content distribution campaign context. In the example shown, a content provider (such as the content provider described with reference to FIG. 1) provides an input to a user interface element. In response to the input, a content distribution apparatus (such as the content distribution apparatus described with reference to FIGS. 2 and 4) generates a campaign brief. The content distribution apparatus displays a representation of a content distribution campaign to the content provider based on the campaign brief and provides content described by the campaign brief to a user identified by the campaign brief (such as the user described with reference to FIG. 1).

At operation 505, the content provider provides a content provider input to a user interface element. In some cases, the operations of this step refer to, or are performed by, a content provider as described with reference to FIG. 1. For example, in some cases, the content provider selects a user interface element including a suggestion that a content distribution campaign be generated, or provides a text input instructing the content distribution apparatus to generate a content distribution campaign.

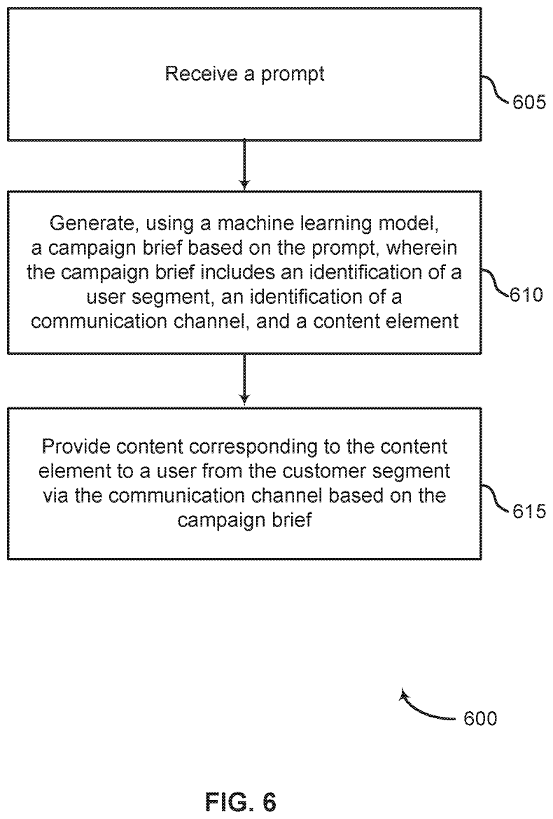

At operation 510, the system generates a campaign brief in response to the content provider input. In some cases, the operations of this step refer to, or are performed by, a content distribution apparatus as described with reference to FIGS. 1 and 2. For example, in some cases, a user experience platform of the content distribution apparatus (such as the user experience platform described with reference to FIGS. 2 and 4) generates a prompt in response to the content provider input, where the prompt includes contextual information and an instruction to generate a campaign brief, as described with reference to FIG. 6. In some cases, a machine learning model of the content distribution apparatus (such as the machine learning model described with reference to FIGS. 2 and 4) generates the campaign brief based on the prompt as described with reference to FIG. 6.

At operation 515, the system displays a visual representation of a campaign according to the campaign brief. In some cases, the operations of this step refer to, or are performed by, a content distribution apparatus as described with reference to FIGS. 1 and 2. For example, in some cases, the content distribution apparatus displays the representation via a user interface as described with reference to FIG. 6.

At operation 520, the system provides content to a user based on the campaign brief. In some cases, the operations of this step refer to, or are performed by, a content distribution apparatus as described with reference to FIGS. 1 and 2. For example, in some cases, the content distribution apparatus provides content identified by the campaign brief to a user identified by the campaign brief via a communication channel identified by the campaign brief as described with reference to FIG. 6.

FIG. 6 shows an example of a method 600 for providing content based on a campaign brief according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 6, a content distribution apparatus (such as the content distribution apparatus described with reference to FIGS. 1 and 2) generates a content distribution campaign brief for a content distribution campaign based on a prompt using a machine learning model trained using training data including a set of campaign briefs (such as the machine learning model described with reference to FIGS. 2 and 4). In some cases, the content distribution apparatus provides content to a user based on the content distribution campaign brief.

Accordingly, by generating the campaign brief using the machine learning model, the content distribution system avoids a time-consuming and labor-intensive process used by conventional content distribution systems of manually creating a campaign brief. Furthermore, by providing content to the identified user according to the generated campaign brief, the content distribution system is able to provide targeted content to a target user in a more efficient manner than conventional content distribution systems.

At operation 605, the system receives a prompt. In some cases, the operations of this step refer to, or are performed by, a machine learning model as described with reference to FIGS. 2 and 4.

In some cases, a user experience platform (such as the user experience platform described with reference to FIGS. 2 and 4) generates the prompt. In some cases, the user experience platform generates the prompt in response to a predetermined trigger event, such as an identification of a data trend or anomaly in data monitored by the user experience platform for the content provider, an identification of a user segment, or any other suitable event.

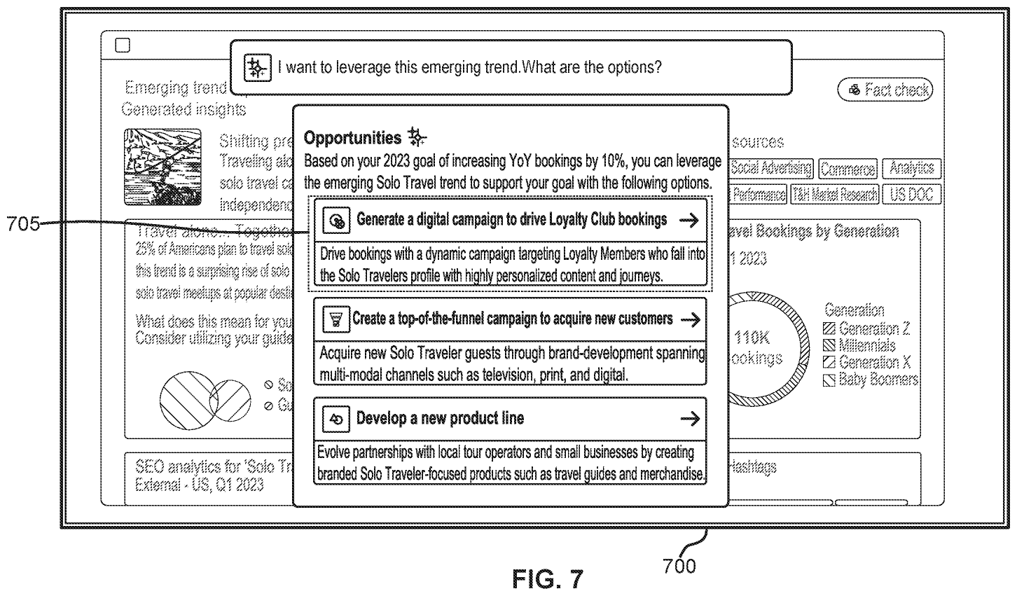

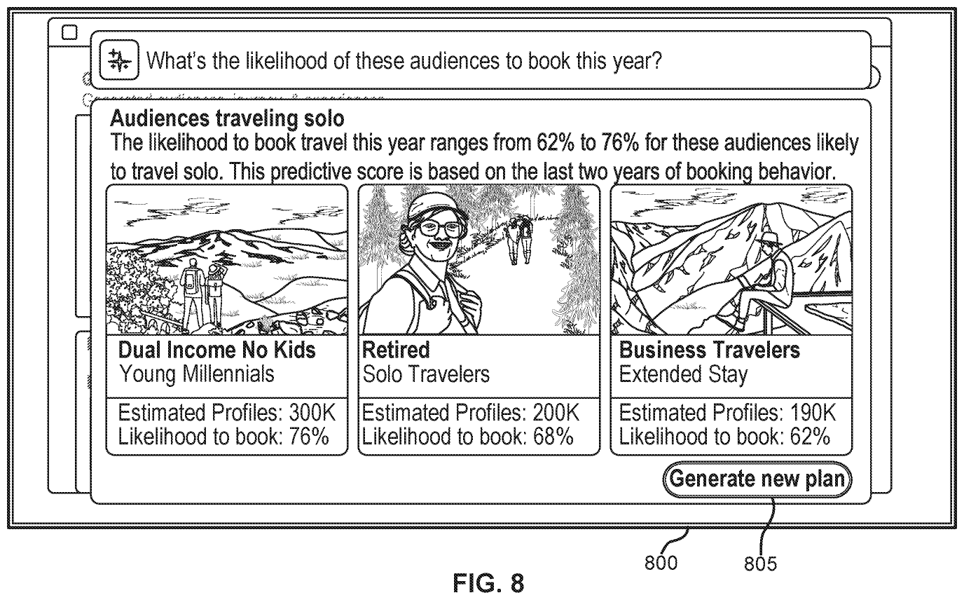

In some cases, the user experience platform displays a suggestion in a campaign generation element of a user interface (such as the user interface described with reference to FIGS. 2 and 7-12) that a content distribution campaign be generated. In some cases, the user experience platform displays the campaign generation element in response to the trigger event. In some cases, the user experience platform generates the prompt in response to a content provider selection of the user interface element. Examples of campaign generation elements are described with reference to FIGS. 7 and 8.

In some cases, the user experience platform generates the prompt in response to a text input from the content provider instructing the content distribution apparatus to generate a campaign.

In some cases, the user experience platform generates the prompt by including contextual information in the prompt. In some cases, contextual information includes one or more of data corresponding to the trigger event, a text description of a suggested content distribution campaign provided by the content generation apparatus, data corresponding to information displayed on a user interface, a content provider profile for the content provider, content provider preferences (such as a content provider goal or objective, a playbook, an additional campaign brief, content preferences, campaign timeline preferences, a preferred user segment, a preferred content distribution channel, and any other information provided by the content provider to the content distribution system), a content provider playbook, historical content distribution campaigns for the content provider, the targeted solo-traveling user segments, a key performance indicator, a user journey for the content provider, previous content provider feedback, and any other available content provider information or user information.

In some cases, the contextual information includes user profiles for users included in the user segment. In some cases, the data corresponding to the trigger event is data that are inclusive of at least one of a foundational enterprise/content distribution focus and a unique content provider-specific foundation.

Examples of data having a foundational enterprise/content distribution focus include publicly available competitor information and announcements, market research reports, brand awareness and perception data, company and industry data, demographic data, seasonal data, macroeconomic data, microeconomic data, and data relating to world events.

Examples of data having a content provider-specific foundation include user and segmentation data, content affinity data based on historical responses to content distribution campaigns, user journey preferences (such as frequency, channels, and content preferences) based on historical performance of content distribution campaigns, share partner or purchased data, historical content distribution campaign details and performance data, brand guidelines and historical content experiences, previous experiments and results, and user research, such as market research and churn analysis.

In some cases, the user experience platform generates the prompt to include an instruction to the machine learning model to generate a campaign brief according to the contextual information included in the prompt. In some cases, the user experience platform generates the prompt to include the text input provided by the content provider. In some cases, a content provider provides the prompt to the machine learning model via the user interface.

At operation 610, the system generates, using the machine learning model, a campaign brief including an identification of a user segment, an identification of a communication channel, and a content element, where the machine learning model is trained using training data including a set of campaign briefs. In some cases, the operations of this step refer to, or are performed by, a machine learning model as described with reference to FIGS. 2 and 4. For example, in some cases, the machine learning model includes a large language model trained to generate the campaign brief based on the prompt. In some cases, the machine learning model includes one or more transformers trained to generate the campaign brief based on the prompt.

In some cases, the campaign brief includes an identification of a user segment, an identification of a communication channel, and a content element. In some cases, the campaign brief identifies a set of audiences including the user segment. In some cases, the machine learning model generates the campaign brief to include the identification of the set of audiences based on one or more of a campaign focus, a campaign goal, a historical affinity, and a performance of a historical campaign brief. In some cases, the campaign brief identifies one or more campaign objectives. In some cases, the campaign brief identifies a ladder-up key performance indicator.

In some cases, the campaign brief identifies a set of periods and a program for each of the set of periods. As used herein, in some cases, a “program” refers to a plotted timeline of content distribution according to the set of periods. In some cases, the communication channel is associated with the program for at least one of the set of periods. In some cases, the set of periods is stage-based. In some cases, the set of periods is calendar-based.

In some cases, the campaign brief includes a description of a user journey. As used herein, in some cases, a “user journey” refers to a process through which a user becomes aware of and interacts with the content provider or a client of the content provider. In some cases, the user journey includes a set of planned touchpoints in which content is provided to the user. In some cases, a touchpoint of the set of planned touchpoints is planned according to one or more of a period of time, an interaction of the user with a content channel (such as a visit to a physical location or a digital content channel such as a social media feed), or an occurrence of a previous touchpoint.

In some cases, the campaign brief includes a set of content elements. In some cases, the set of content elements includes at least one text element and at least one visual element. In some cases, the campaign brief includes a summary of the content distribution campaign corresponding to the campaign brief. In some cases, the summary comprises a natural language statement. In some cases, the campaign brief includes a title or a label for the content distribution campaign.

In some cases, the campaign brief includes instructions for the user experience platform to retrieve content from a database (such as the database described with reference to FIG. 1). For example, in some cases, a content element included in the campaign brief includes an instruction to retrieve content described by one or more keywords included in the content element. In some cases, the campaign brief includes instructions for the user experience platform to generate content. For example, in some cases, the content element includes a description of content to be generated by a generative machine learning model of the user experience platform. In some cases, the campaign brief includes instructions for the user experience platform to combine two or more items of content (e.g., a text element and an image element).

In some cases, the campaign brief includes instructions for the user experience platform to provide a visual representation of the content distribution campaign corresponding to the campaign brief. For example, in some cases, the campaign brief includes instructions to display one or more of a representation of a program, content, a summary of the content distribution campaign, a user segment, a goal or objective for the content distribution campaign, and the title or label for the content distribution campaign. An example of a representation of a content distribution campaign provided according to a campaign brief is described with reference to FIG. 9.

In some cases, the content distribution apparatus receives content provider feedback for the campaign brief and modifies the campaign brief based on the content provider feedback using the machine learning model. In an example, a content provider identifies additional information to the user interface for modifying the campaign brief (for example, an identification of an additional user segment). In response to receiving the additional information, the user experience platform provides the additional information as input to the machine learning model and instructs the machine learning model to modify the campaign brief based on the additional information. In some cases, the campaign brief includes instructions to retrieve, generate, and/or display a visual representation of information corresponding to the additional information. An example of a visual representation of a modified campaign brief is described with reference to FIG. 10.

According to some aspects, the user experience platform evaluates the campaign brief based on ethics, accessibility, intellectual property compliance, or any combination thereof. In some cases, the user experience platform evaluates the campaign brief based on a compliance algorithm. In some cases, the user experience platform evaluates the campaign brief by providing the campaign brief to an evaluation team member for evaluation.

Therefore, according to some aspects, the content distribution apparatus provides a complete content distribution campaign package, including a program, messaging, content, and a user experience journey, based on a campaign brief generated by the machine learning model, to provide targeted content for a target audience according to an objective for the content distribution campaign. In some cases, the content distribution campaign package is provided by leveraging historical campaigns, optimizing content generation using content performance analytics aligned to brand guidelines, and undergoing compliance checks for ethics, accessibility, and intellectual property.

At operation 615, the system provides content corresponding to the content element to a user from the user segment via the communication channel based on the campaign brief. In some cases, the operations of this step refer to, or are performed by, a user experience platform as described with reference to FIGS. 2 and 4.

Therefore, according to some aspects, the content distribution apparatus provides targeted content to a target user in a more efficient manner than conventional content distribution systems provide.

In some cases, the user experience platform selectively includes content corresponding to the set of content elements in a set of communications corresponding to a set of user segments, respectively.

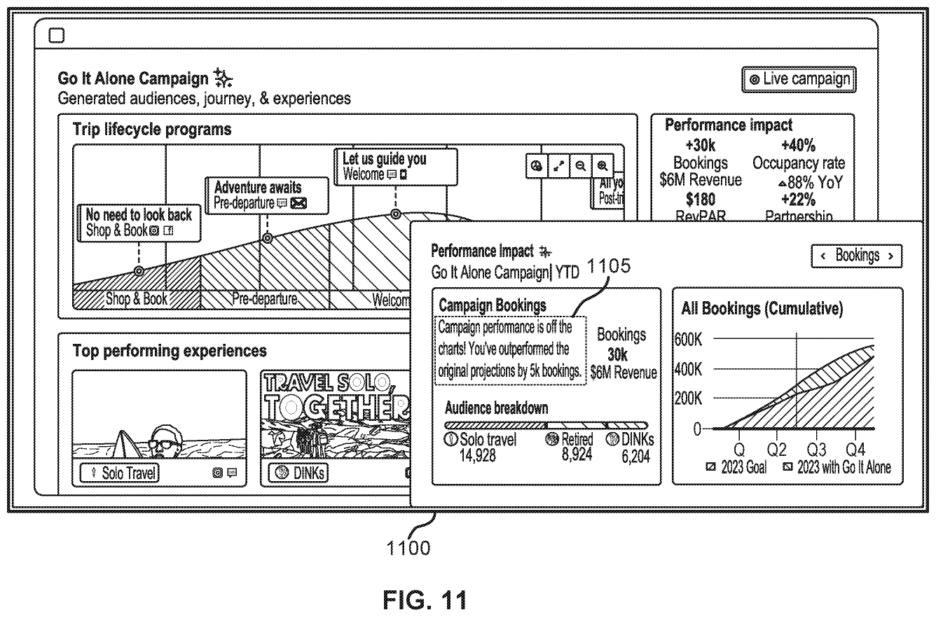

In some cases, the user experience platform monitors a performance of the content distribution campaign corresponding to the campaign brief according to a metric or goal. In some cases, the user experience platform provides information relating to the performance of the content distribution campaign to the machine learning model. In some cases, the machine learning model generates a statement corresponding to the performance of the content distribution campaign based on the provided information. In some cases, the user experience platform displays the statement corresponding to the performance of the content distribution campaign. An example of a display of a statement corresponding to the performance of the content distribution campaign is provided with reference to FIG. 11.

In some cases, the content distribution apparatus optimizes and adjusts a content distribution campaign via implicit and/or explicit feedback from one or more of the content provider, the user, or the client of the content provider. In some cases, real-world behavior and performance of the content distribution campaign therefore feeds back to the content distribution apparatus to rebalance and optimize subsequent tactics for the content distribution campaign in real time.

For example, in some cases, the content distribution apparatus uses the machine learning model to generate an additional campaign brief for an active content distribution campaign (e.g., a content distribution campaign corresponding to content that has been provided to a user) based on an additional prompt.

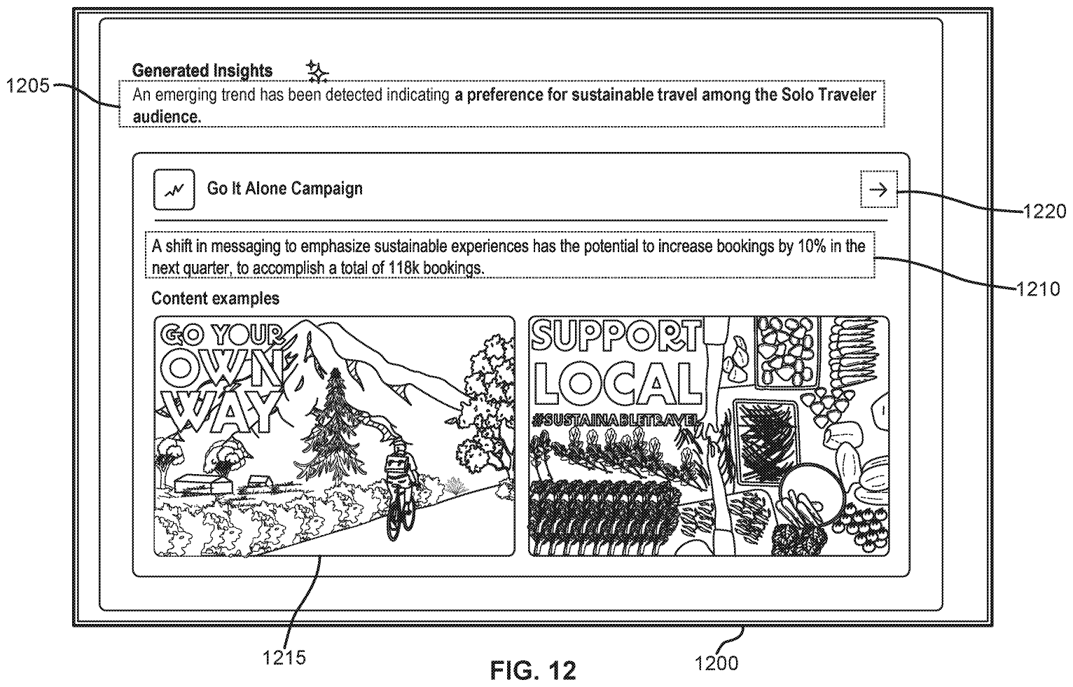

In some cases, the user experience platform detects an additional trigger event (such as a data trend or anomaly) in data corresponding to the active content distribution campaign. In some cases, the user experience platform generates an additional prompt based on the additional trigger event and contextual information corresponding to the additional trigger event. In some cases, the user interface displays a campaign modification element including a suggestion that the active content distribution campaign be modified based on the additional trigger event. In some cases, the user experience platform generates the additional prompt based on a content provider input to the campaign generation element. In some cases, the user experience platform generates the additional prompt based on a text input instructing the user experience platform to modify the active content distribution campaign. An example of a user interface for modification of a campaign is described with reference to FIG. 12.

FIG. 7 shows an example of a user interface for campaign generation according to aspects of the present disclosure. The example shown includes user interface 700 and campaign generation element 705. User interface 700 is an example of, or includes aspects of, the corresponding element described with reference to FIGS. 2 and 8-12. Campaign generation element 705 is an example of, or includes aspects of, the corresponding element described with reference to FIG. 8.

Referring to FIG. 7, user interface 700 displays campaign generation element 705 in response to a content provider input indicating that a detected trend of increased solo travelers should be leveraged. In the example of FIG. 7, campaign generation element 705 includes a suggestion that the content distribution system (such as the content distribution system described with reference to FIGS. 1 and 4) be used to generate a digital campaign to drive loyalty bookings targeting loyalty members included in a solo traveler user segment. In some cases, a user experience platform (such as the user experience platform described with reference to FIGS. 2 and 4) generates a prompt based on a content provider input to campaign generation element 705 as described with reference to FIG. 6, where the prompt includes contextual information corresponding to user interface 700.

FIG. 8 shows an example of a user interface for campaign generation based on a user segment according to aspects of the present disclosure. The example shown includes user interface 800 and campaign generation element 805. User interface 800 is an example of, or includes aspects of, the corresponding element described with reference to FIGS. 2, 7, and 9-12. Campaign generation element 805 is an example of, or includes aspects of, the corresponding element described with reference to FIG. 7.

Referring to FIG. 8, user interface 800 displays campaign generation element 805 in response to a content provider query regarding a set of user segments. In the example of FIG. 8, campaign generation element 805 corresponds to an indication of likelihoods of the user segments to book travel in the year. In some cases, a user experience platform (such as the user experience platform described with reference to FIGS. 2 and 4) generates a prompt based on a content provider input to campaign generation element 805 as described with reference to FIG. 6, where the prompt includes contextual information corresponding to user interface 800.

FIG. 9 shows an example of a user interface for a content distribution campaign according to aspects of the present disclosure. The example shown includes user interface 900, campaign representation 905, campaign label 910, program representation 915, campaign summary 920, user segment label element 925, user segment size 930, campaign goal element 935, visual content representation 940, text content representation 945, call to action (CTA) content representation 950, view composed examples element 955, and send for approval element 960.

User interface 900 is an example of, or includes aspects of, the corresponding element described with reference to FIGS. 2, 7, 8, and 10-12. Campaign representation 905 is an example of, or includes aspects of, the corresponding element described with reference to FIG. 4. Program representation 915 is an example of, or includes aspects of, the corresponding element described with reference to FIG. 10.

Referring to FIG. 9, in some cases, user interface 900 displays campaign representation 905 of a content distribution campaign according to a campaign brief generated by a machine learning model as described with reference to FIG. 6. As shown, campaign representation 905 includes campaign label 910, program representation 915, campaign summary 920, user segment label element 925, user segment size 930 (e.g., a representation of a number of user profiles corresponding to user segment label element 925), campaign goal element 935, visual content representation 940, text content representation 945, and CTA content representation 950.

In some cases, a content provider input provided to view composed examples element 955 displays additional representations of content provided by the user experience platform according to content elements included in the campaign brief. In an example, a content provider input provided to send for approval element 960 allows the content provider to share campaign representation 905 with an additional party.

FIG. 10 shows an example of a user interface for a modified content distribution campaign according to aspects of the present disclosure. The example shown includes user interface 1000, campaign representation 1005, additional campaign lifecycle feature 1010, user segment labels elements 1015, modified visual content representation 1020, and modified text content representation 1025.

User interface 1000 is an example of, or includes aspects of, the corresponding element described with reference to FIGS. 2, 7-9, 11, and 12. Campaign representation 1005 is an example of, or includes aspects of, the corresponding element described with reference to FIG. 9.

In some cases, a campaign brief is modified according to content provider feedback such as additional information as described with reference to FIG. 6. As shown in FIG. 10, campaign representation 1005 displayed by user interface 1000 has been modified from the campaign representation shown in FIG. 9 based on a modified campaign brief. In an example, a content provider has added two user segments (Dual Income No Kids and Retired) as user segments for the content distribution campaign, the machine learning model has generated a modified campaign brief based on the additional information, and campaign representation 1005 has accordingly been modified to include additional campaign lifecycle feature 1010, user segment labels elements 1015, modified visual content representation 1020, and modified text content representation 1025.

FIG. 11 shows an example of a user interface for evaluating a performance of a content distribution campaign according to aspects of the present disclosure. The example shown includes user interface 1100 and performance evaluation 1105. User interface 1100 is an example of, or includes aspects of, the corresponding element described with reference to FIGS. 2, 7-10, and 12.

In some cases, a machine learning model generates a description of a performance of an active content distribution campaign as described with reference to FIG. 6. As shown in FIG. 11, user interface 1100 displays performance evaluation 1105 generated by the machine learning model.

FIG. 12 shows an example of a user interface for modification of a campaign according to aspects of the present disclosure. The example shown includes user interface 1200, data trend summary 1205, campaign modification suggestion 1210, suggested content 1215, and campaign modification element 1220. User interface 1200 is an example of, or includes aspects of, the corresponding element described with reference to FIGS. 2 and 7-11.

In some cases, an additional prompt for modifying an active content distribution campaign is generated based on additional data as described with reference to FIG. 6. In the example of FIG. 12, user interface 1200 displays data trend summary 1205 summarizing a data trend and campaign modification suggestion 1210 describing a suggested modification to the campaign in view of the data trend. In some cases, user interface 1200 displays suggested content 1215 provided by the user experience platform in response to the data trend. In some cases, a content provider instructs the user experience platform to generate an additional prompt by providing an input to campaign modification element 1220.

### Training

A method for content distribution is described with reference to FIG. 13. One or more aspects of the method include obtaining training data that includes a training prompt and a ground-truth campaign brief and training a machine learning model to generate a campaign brief including an identification of a user segment, an identification of a communication channel, and a content element using the training data.

In some aspects, the campaign brief identifies a plurality of audiences including the user segment. In some aspects, the campaign brief identifies one or more campaign objectives. In some aspects, the campaign brief identifies a plurality of periods and a program for each of the plurality of periods, wherein the communication channel is associated with the program for at least one of the plurality of periods. In some aspects, the campaign brief includes a plurality of content elements. In some aspects, the plurality of content elements includes at least one text element and at least one visual element.

FIG. 13 shows an example of a method 1300 for training a machine learning model according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 1305, the system obtains training data that includes a training prompt and a ground-truth campaign brief. In some cases, the operations of this step refer to, or are performed by, a training component as described with reference to FIG. 2. For example, in some cases, the training prompt is a prompt as described herein, and the ground-truth campaign brief is a campaign brief as described herein. In some cases, the training component obtains the training data from a database (such as the database described with reference to FIG. 1) or from another data source (such as the Internet). In some cases, the training data includes a set of training prompts and a corresponding set of ground-truth campaign briefs. In some cases, the training data includes a ground-truth program (e.g., a program as described herein). In some cases, the training data includes a ground-truth task. In some cases, the training data includes ground-truth content. In some cases, the training data includes a ground-truth key performance indicator.

At operation 1310, the system trains a machine learning model to generate a campaign brief including an identification of a user segment, an identification of a communication channel, and a content element using the training data. In some cases, the operations of this step refer to, or are performed by, a training component as described with reference to FIG. 2.

For example, in some cases, the training component provides one or more training prompts to a machine learning model (such as the machine learning model described with reference to FIGS. 2 and 4). In some cases, the machine learning model generates a campaign brief based on the one or more training prompts as described with reference to FIG. 6. In some cases, the training component compares the campaign brief to the one or more ground-truth campaign briefs corresponding to the one or more training prompts to determine a loss function. In some cases, the loss function is determined based on one or more of the ground-truth program, the ground-truth task, the ground-truth content, and the ground-truth key performance indicator.

The term “loss function” refers to a function that impacts how a machine learning model is trained in a supervised learning model. For example, during each training iteration, the output of the machine learning model is compared to the known annotation information in the training data. The loss function provides a value (a “loss”) for how close the predicted annotation data is to the actual annotation data. After computing the loss, the parameters of the model are updated accordingly and a new set of predictions are made during the next iteration.

Supervised learning is one of three basic machine learning paradigms, alongside unsupervised learning and reinforcement learning. Supervised learning is a machine learning technique based on learning a function that maps an input to an output based on example input-output pairs. Supervised learning generates a function for predicting labeled data based on labeled training data consisting of a set of training examples. In some cases, each example is a pair consisting of an input object (typically a vector) and a desired output value (i.e., a single value, or an output vector). In some cases, a supervised learning algorithm analyzes the training data and produces the inferred function, which is used for mapping new examples. In some cases, the learning results in a function that correctly determines the class labels for unseen instances. In other words, the learning algorithm generalizes from the training data to unseen examples.

In some cases, the training component trains the machine learning model by updating the machine learning parameters of the machine learning model according to the loss function.

The description and drawings described herein represent example configurations and do not represent all the implementations within the scope of the claims. For example, the operations and steps can be rearranged, combined, or otherwise modified. Also, in some cases, structures and devices are represented in the form of block diagrams to represent the relationship between components and avoid obscuring the described concepts. Similar components or features can have the same name but can have different reference numbers corresponding to different figures.

Some modifications to the disclosure are readily apparent to those skilled in the art, and the principles defined herein can be applied to other variations without departing from the scope of the disclosure. Thus, the disclosure is not limited to the examples and designs described herein, but is to be accorded the broadest scope consistent with the principles and novel features disclosed herein.

In some embodiments, the described methods are implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. In some embodiments, a general-purpose processor is a microprocessor, a conventional processor, controller, microcontroller, or state machine. In some embodiments, a processor is implemented as a combination of computing devices (e.g., a combination of a DSP and a microprocessor, multiple microprocessors, one or more microprocessors in conjunction with a DSP core, or any other such configuration). Thus, in some embodiments, the functions described herein are implemented in hardware or software and are executed by a processor, firmware, or any combination thereof. In some embodiments, if implemented in software executed by a processor, the functions are stored in the form of instructions or code on a computer-readable medium.

Computer-readable media includes both non-transitory computer storage media and communication media including any medium that facilitates transfer of code or data. In some embodiments, a non-transitory storage medium is any available medium that is accessible by a computer. For example, in some cases, non-transitory computer-readable media comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, in some embodiments, connecting components are properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” can be based on both condition A and condition B. In other words, the phrase “based on” shall be construed to mean “based at least in part on.” Also, the words “a” or “an” indicate “at least one.”

What is claimed is:

1. A method for content distribution, comprising:
receiving, by a machine learning model, a prompt;
generating, using the machine learning model, a campaign brief based on the prompt, wherein the campaign brief includes an identification of a user segment, an identification of a communication channel, and a content element, and wherein the machine learning model is trained using training data including a plurality of campaign briefs; and
providing, by a user experience platform, content corresponding to the content element to a user from the user segment via the communication channel based on the campaign brief.

2. The method of claim 1, wherein:
the campaign brief identifies a plurality of audiences including the user segment.

3. The method of claim 1, wherein:
the campaign brief identifies one or more campaign objectives.

4. The method of claim 1, wherein:
the campaign brief identifies a plurality of periods and a program for each of the plurality of periods, wherein the communication channel is associated with the program for at least one of the plurality of periods.

5. The method of claim 1, wherein:
the campaign brief includes a plurality of content elements.

6. The method of claim 5, wherein:
the plurality of content elements includes at least one text element and at least one visual element.

7. The method of claim 5, further comprising:
selectively including, by the user experience platform, content corresponding to the plurality of content elements in a plurality of communications corresponding to a plurality of user segments, respectively.

8. The method of claim 1, further comprising:
evaluating, by the user experience platform, the campaign brief based on ethics, accessibility, intellectual property compliance, or any combination thereof.

9. The method of claim 1, further comprising:
receiving, by the machine learning model, content provider feedback for the campaign brief and modifying the campaign brief based on the content provider feedback using the machine learning model.

10. A method for content distribution, comprising:
obtaining, by a training component, training data that includes a training prompt and a ground-truth campaign brief; and
training, by the training component, a machine learning model to generate a campaign brief including an identification of a user segment, an identification of a communication channel, and a content element using the training data.

11. The method of claim 10, wherein:
the campaign brief identifies a plurality of audiences including the user segment.

12. The method of claim 10, wherein:
the campaign brief identifies one or more campaign objectives.

13. The method of claim 10, wherein:
the campaign brief identifies a plurality of periods and a program for each of the plurality of periods, wherein the communication channel is associated with the program for at least one of the plurality of periods.

14. The method of claim 10, wherein:
the campaign brief includes a plurality of content elements.

15. The method of claim 14, wherein:
the plurality of content elements includes at least one text element and at least one visual element.

16. An apparatus for content distribution, comprising:
at least one processor;
at least one memory storing instructions executable by the at least one processor;
a machine learning model including language model parameters stored in the at least one memory and trained to generate a campaign brief based on a prompt, wherein the campaign brief includes an identification of a user segment, an identification of a communication channel, and a content element; and
a user experience platform configured to provide content corresponding to the content element to a user from the user segment via the communication channel based on the campaign brief.

17. The apparatus of claim 16, wherein:
the campaign brief identifies a plurality of audiences including the user segment.

18. The apparatus of claim 16, wherein:
the campaign brief identifies one or more campaign objectives.

19. The apparatus of claim 16, wherein:
the campaign brief identifies a plurality of periods and a program for each of the plurality of periods, wherein the communication channel is associated with the program for at least one of the plurality of periods.

20. The apparatus of claim 16, wherein:
the campaign brief includes a plurality of content elements.
